(19) United States
(12) Patent Application Publication
(10) Pub. No.: US 2020/0194464 A1
(43) Pub. Date: Jun. 18, 2020

(54) ARRAY SUBSTRATE AND METHOD FOR MANUFACTURING SAME

(71) Applicant: Wuhan China Star Optoelectronics Technology Co., Ltd., Wuhan (CN)

(72) Inventor: Shidi XIAO, (US)

(73) Assignee: Wuhan China Star Optoelectronics Technology Co., Ltd., Wuhan (CN)

(21) Appl. No.: 16/332,810

(22) PCT Filed: Jan. 29, 2019
(86) PCT No.: PCT/CN2019/073556

§ 371 Date: Mar. 13, 2019

(30) Foreign Application Priority Data
Dec. 17, 2018 (CN) 201811545208.6

(51) Int. Cl. H01L 27/12; G02F 1/1343; G02F 1/136

(52) U.S. Cl. CPC H01L 27/1218; G02F 1/136; H01L 27/127; G02F 1/134309

(57) ABSTRACT

The present disclosure provides an array substrate and a method for manufacturing same. The pixel electrode of the array sub substrate includes an effective active area and a parallelogram-shaped etched area, wherein the etched area is formed using a mask having a transparent area by performing an etching process; wherein the mask comprises a shielding area and the transparent area corresponding to the etched area, a pattern defined by a circumference of the transparent area has a shape of a parallelogram, and both a top side and a bottom side of the circumference of the transparent area includes an exposure compensation area extending towards the shielding area.

### FIELD OF INVENTION

The present disclosure relates to a field of display technology, and more particularly to an array substrate and a method for manufacturing same.

### BACKGROUND

TFT-LCD display panels have been widely used to produce mobile phones, tablets, and computers that require small-sized panels. By increasing light transparency of panels, display qualities of display panels can be efficiently raised, and in the meanwhile, power consumption of display panels is lowered to increase battery life of electronic products.

However, in conventional manufacturing process of display panels, because manufacturing equipment has a limited process accuracy, or interference and diffraction of light occur during exposure and etching, actual pixel electrode patterns formed generally does not match an intended pixel electrode pattern.

For this reason, the formed pixel electrode includes an incompletely etched arc portion at top and bottom of boundary between effective active area and etched area. In addition, because etched area does not have a shape that matches a shape intended to be formed, an electric field near the etched area disturbs an electric field in effective active area. This further disturbs rotation of liquid crystal molecules, and makes display panels have a low light transparency.

### SUMMARY OF DISCLOSURE

### Technical Problems

The formed pixel electrode includes an incompletely etched arc portion at top and bottom of boundary between effective active area and etched area. In addition, because etched area does not have a shape matching shape intended to be formed, electric filed near etched area disturbs electric field in effective active area. This affects rotation of liquid crystal molecules, and makes display panels have a low light transparency.

### Technical Solution

The present disclosure provides an array substrate comprising a baseplate and a pixel electrode disposed on the baseplate, the pixel electrode including an effective active area and a parallelogram-shaped etched area, wherein the etched area is formed using a mask having a transparent area by performing an etching process;

wherein the mask comprises a shielding area and the transparent area corresponding to the etched area, a pattern defined by a circumference of the transparent area has a shape of a parallelogram, and both a top side and a bottom side of the circumference of the transparent area includes an exposure compensation area extending towards the shielding area.

Additionally, each of the exposure compensation areas includes two corner compensation areas at edge corners of the transparent area.

Additionally, each of the exposure compensation areas further includes a side compensation area located between the two corner compensation areas, and the two corner compensation areas are connected to the side compensation area.

Additionally, a circumference of the corner compensation area has a shape of a diamond, a first lateral side of the circumference of the corner compensation area is parallel to a second lateral side of the circumference of the transparent area, and a top side of the circumference of the corner compensation area is parallel to the top side of the circumference of the transparent area.

Additionally, the first lateral side and the second lateral side located at a same side of the transparent area are distanced from each other by a distance a, the top side and a bottom side of the circumference of the corner compensation area are distanced from each other by a distance b, and a top side and a bottom side of the circumference of the side compensation area are distanced from each other by a distance c equal to a value obtained by subtraction of a from b.

Additionally, each of the corner compensation areas includes two first compensation areas, both circumferences of the two first compensation areas have a same shape and size of a right triangle, a side of the circumference of the first compensation area overlaps with a lateral side of the circumference of the transparent area, and a boundary between the first compensation area and the shielding area is a hypotenuse of the circumference of the first compensation area; and one of the first compensation areas of each corner compensation area is located at a lateral portion of the transparent area, the other first compensation area of the each corner compensation area is located at a top portion or a bottom portion of the transparent area, and the two first compensation areas of each corner compensation area partially overlap with each other.

Additionally, each of the corner compensation areas includes two second compensation areas, one of the second compensation areas of each corner compensation area is located at a lateral portion of the transparent area, the other second compensation area of the each corner compensation area is located at a top portion or a bottom portion of the transparent area, and a boundary between each second compensation area and the shielding area has a shape of a continuous wave.

Additionally, each of the second compensation areas includes at least three triangular compensation areas, a circumference of each triangular compensation area has a shape of an isosceles triangle, bases of circumferences of the at least three triangular compensation areas of each second compensation area are of a same length, and legs of circumferences of the at least three triangular compensation areas of each second compensation area are of different length; and the base of the circumference of the triangular compensation area is distanced from a corresponding edge corner of the transparent area by a distance S 1, the leg of the circumference of the triangular compensation area has a length of K, and K is inversely proportional to S1.

Additionally, each of the second compensation areas includes at least three rectangular compensation areas, a circumference of each rectangular compensation area has a shape of a rectangle, the circumference of each rectangular compensation area includes a first straight side and a second straight side remote from the transparent area and parallel to the first straight side, the first straight side of the rectangular compensation area located at the bottom portion or the top portion of the transparent area is parallel to the bottom side of the circumference of the transparent area, and the first straight side of the rectangular compensation area located at the lateral portion of the transparent area is parallel to a lateral side of the circumference of the transparent area; and the rectangular compensation area is distanced from the corresponding edge corner of the transparent area by a distance S2, the first straight side and the second straight side of each rectangular compensation area are distanced from each other by a distance h, the first straight sides of the at least rectangular compensation areas are of a same length, and h of the at least rectangular compensation areas is inversely proportional to S2.

The present disclosure further provides a method for manufacturing an array substrate, comprising:

a step S10 of forming a pixel electrode on a baseplate, the pixel electrode including an effective active area and an etched area;

a step S20 of etching the etched area of the pixel electrode using a mask by performing an etching process, so as to form a parallelogram-shaped etched area of the pixel electrode;

wherein the mask comprises a shielding area and a transparent area corresponding to the etched area, a pattern defined by a circumference of the transparent area has a shape of a parallelogram, and both a top side and a bottom side of the circumference of the transparent area includes an exposure compensation area extending towards the shielding area.

### Advantageous Effects

By using a mask to etch the pixel electrode, wherein both a top side and a bottom side of the circumference of the transparent area of the mask includes an exposure compensation area, and by providing various masks that have different compensation designs to improve the pattern of the manufactured pixel electrode, the pixel electrode thus formed can has a pattern matching the theoretically designed shape, thus increasing light transparency of display panels.

### BRIEF DESCRIPTION OF DRAWINGS

To detailedly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 shows a top view of an array substrate according to the present disclosure.

FIG. 2 shows a top view of a mask according to EMBODIMENT ONE of the present disclosure.

FIG. 3 shows a top view of a mask according to EMBODIMENT TWO of the present disclosure.

FIG. 4 shows a top view of a mask according to EMBODIMENT THREE of the present disclosure.

FIG. 5 shows a top view of a mask according to EMBODIMENT FOUR of the present disclosure.

### DETAILED DESCRIPTION

The following embodiments refer to the accompanying drawings for exemplifying specific implementable embodiments of the present disclosure. Moreover, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, the same reference symbol represents the same or similar components.

The present disclosure solves the problems existing in prior art, where in conventional manufacturing process of display panels, because manufacturing equipment has limit in process accuracy, or interference and diffraction of light occur during exposure and etching treatment, pattern of pixel electrode formed thereby generally does not match pattern of pixel electrode intended to be formed.

### Embodiment One

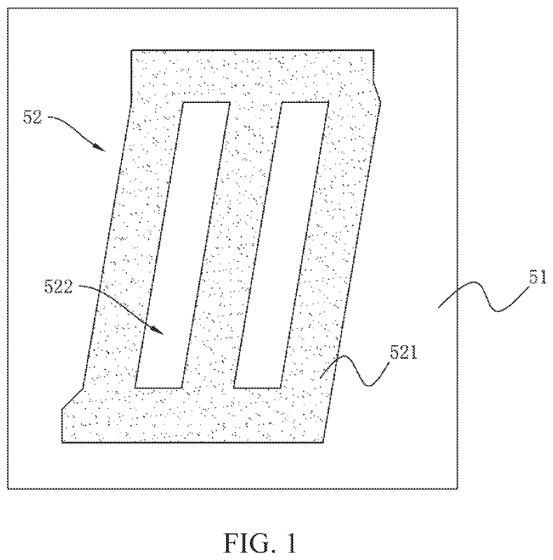

An array substrate, as shown in FIG. 1, comprises a baseplate 51 and a pixel electrode 52 disposed on the baseplate 51, the pixel electrode 52 including an effective active area 521 and a parallelogram-shaped etched area 522, wherein the etched area 522 is formed using a mask 10 having a transparent area 12 by performing an etching process.

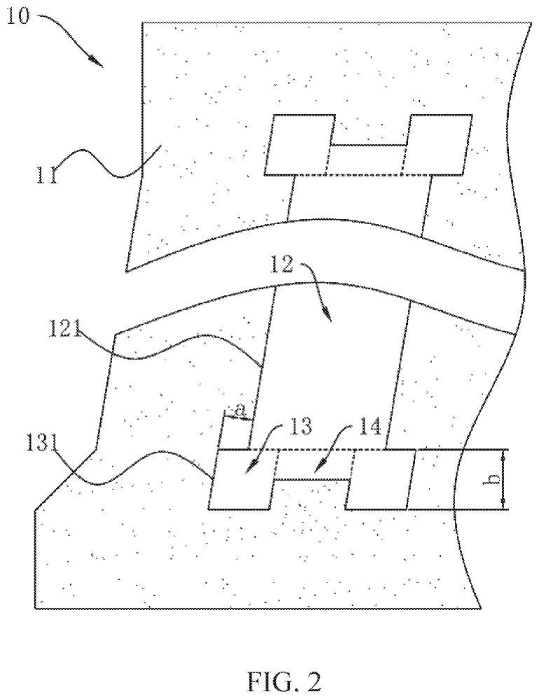

The mask 10, as shown in FIG. 2, comprises a shielding area 11 and the transparent area 12 corresponding to the etched area 522, a pattern defined by a circumference of the transparent area 12 has a shape of a parallelogram, and both a top side and a bottom side of the circumference of the transparent area 12 includes an exposure compensation area extending towards the shielding area 11.

Specifically, each of the exposure compensation areas includes two corner compensation areas 13 at edge corners of the transparent area 12.

Moreover, each of the exposure compensation areas further includes a side compensation area 14 located between the two corner compensation areas 13, and the two corner compensation areas 13 are connected to the side compensation area 14.

A circumference of the corner compensation area 13 has a shape of a diamond, a first lateral side 131 of the circumference of the corner compensation area 13 is parallel to a second lateral side 121 of the circumference of the transparent area 12, and a top side of the circumference of the corner compensation area 13 is parallel to the top side of the circumference of the transparent area 12.

With the mask 10 having the exposure compensation area, the pixel electrode formed using the mask 10 can has a pattern matching the theoretically designed shape. Therefore, the produced display panels generate optical effects that are more consistent with the theoretically designed values, thus increasing light transparency of display panels.

In addition, the first lateral side 131 and the second lateral side 132 located at a same side of the transparent area 12 are distanced from each other by a distance a. The top side and a bottom side of the circumference of the corner compensation area 13 are distanced from each other by a distance b. A top side and a bottom side of the circumference of the side compensation area 14 are distanced from each other by a distance c equal to a value obtained by subtraction of a from b.

It is understood that, in practice, the values a and b are determined based on the size of pixel electrode that is to be formed. The greater the size of the pixel electrode, the greater the values a and b.

### Embodiment Two

An array substrate having a pixel electrode 52, wherein the etched area 522 of the pixel electrode 52 is formed using a mask 10 by performing an etching process.

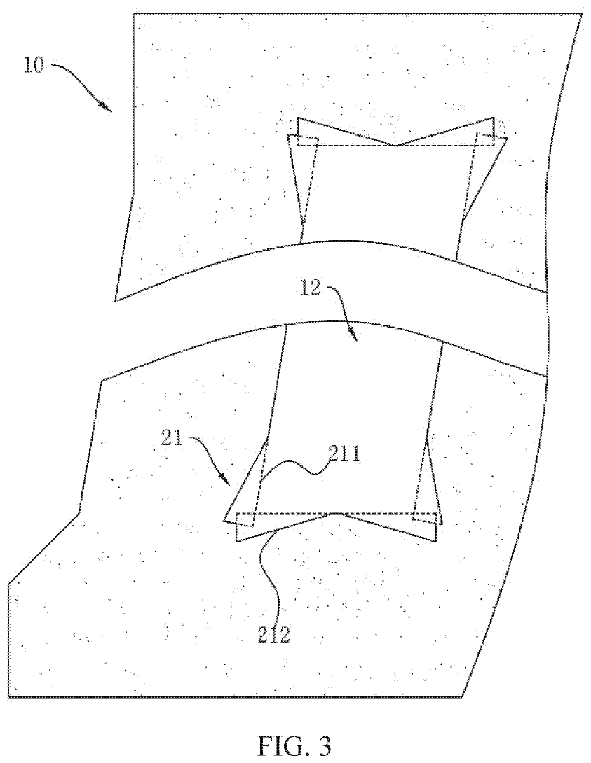

The mask 10 in the present embodiment, as shown in FIG. 3, differs from EMBODIMENT ONE in that the circumference of the exposure compensation area of the mask 10 has a different shape.

Specifically, each of the exposure compensation areas includes two corner compensation areas 13 at edge corners of the transparent area 12.

Each of the corner compensation areas 13 includes two first compensation areas 21, both circumferences of the two first compensation areas 21 have a same shape and size of a right triangle, a side 211 of the circumference of the first compensation area 21 overlaps with a lateral side of the circumference of the transparent area 12, and a boundary between the first compensation area 21 and the shielding area 11 is a hypotenuse 212 of the circumference of the first compensation area 21.

Moreover, one of the first compensation areas 21 of each corner compensation area 13 is located at a lateral portion of the transparent area 12, the other first compensation area 21 of the each corner compensation area 13 is located at a top portion or a bottom portion of the transparent area 12, the two first compensation areas 21 of each corner compensation area 13 partially overlap with each other, and the hypotenuses 212 of the circumferences of the two first compensation areas 21 cross each other.

It is understood that, in practice, the length of the hypotenuse 212 of the circumference of the two first compensation area 21 and the angle between the hypotenuse 212 and the side 211 are determined based on the size of pixel electrode that is to be formed. The greater the size of the pixel electrode, the greater the length of the side 211 of the circumference of the first compensation area 21.

In the process using the mask 10 to perform exposure and etching treatment on the pixel electrode to form the etch area 522 of the pixel electrode, region that is more proximate to edge corners of the etched corner 522 would have more remained portion. With the corner compensation area 13 formed at edge corners of the transparent area 12, the pixel electrode formed using the mask 10 can has a pattern matching the theoretically designed shape.

### Embodiment Three

An array substrate having a pixel electrode 52, wherein the etched area 522 of the pixel electrode 52 is formed using a mask 10 by performing an etching process.

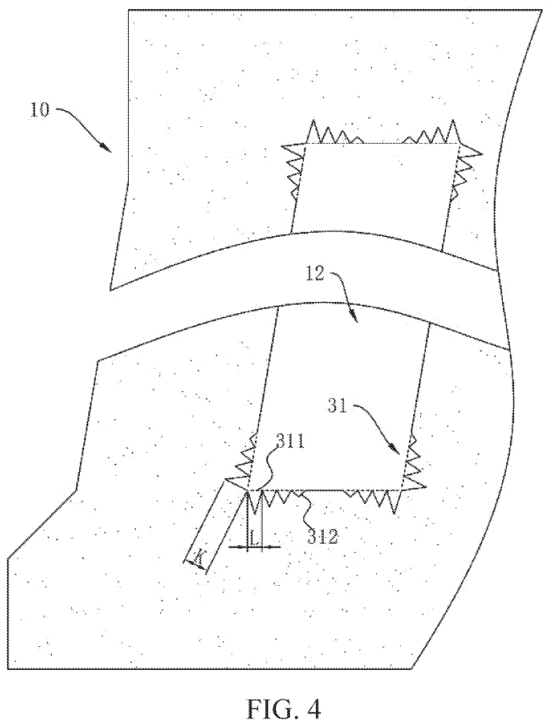

The mask 10 in the present embodiment, as shown in FIG. 4, differs from EMBODIMENT ONE in that the circumference of the exposure compensation area of the mask 10 has a different shape.

Specifically, each of the exposure compensation areas includes two corner compensation areas 13 at edge corners of the transparent area 12.

Each of the corner compensation areas 13 includes two second compensation areas 31, one of the second compensation areas 31 of each corner compensation area 13 is located at a lateral portion of the transparent area 12, the other second compensation area 31 of the each corner compensation area 13 is located at a top portion or a bottom portion of the transparent area 12, and a boundary between each second compensation area 31 and the shielding area 11 has a shape of a continuous wave

Moreover, each of the second compensation areas 31 includes at least three triangular compensation areas 13, a circumference of each triangular compensation area 13 has a shape of an isosceles triangle, bases of circumferences of the at least three triangular compensation areas 13 of each second compensation area 31 are of a same length, and legs 312 of circumferences of the at least three triangular compensation areas 13 of each second compensation area 31 are of different length.

The base 311 of circumference of the triangular compensation area 13 has a length of L, the base 311 of the circumference of the triangular compensation area 13 is distanced from a corresponding edge corner of the transparent area 12 by a distance S1, the leg 312 of the circumference of the triangular compensation area 13 has a length of K, and K is inversely proportional to S1. That is, the greater the value S1, the smaller the value K.

It is understood that, in practice, the values of L, S1, and K are determined based on the size of pixel electrode that is to be formed. The greater the size of the pixel electrode, the greater the values of L, S1, and K.

In addition, FIG. 4 shows that each second compensation area 31 includes only four triangular compensation areas 13. However, in practice, the greater the size of the pixel electrode, the greater the length of the bottom side of the circumference of the transparent area 12. Therefore, each second compensation area 31 would include more triangular compensation areas 13.

### Embodiment Four

An array substrate having a pixel electrode 52, wherein the etched area 522 of the pixel electrode 52 is formed using a mask 10 by performing an etching process.

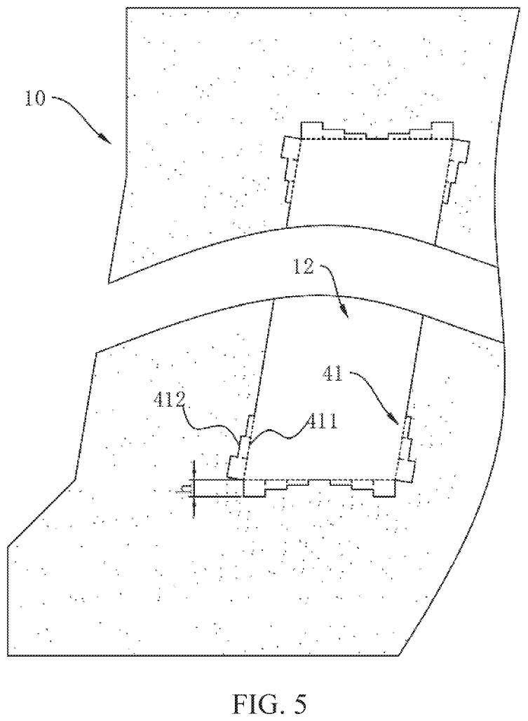

The mask 10 in the present embodiment, as shown in FIG. 5, differs from EMBODIMENT THREE in that the circumference of the second compensation area 31 has a different shape.

Specifically, each of the second compensation areas 31 includes at least three rectangular compensation areas 41, a circumference of each rectangular compensation area 41 has a shape of a rectangle, the circumference of each rectangular compensation area 41 includes a first straight side 411 and a second straight side 412 remote from the transparent area 12 and parallel to the first straight side 411, the first straight side 411 of the rectangular compensation area 41 located at the bottom portion or the top portion of the transparent area 12 is parallel to the bottom side of the circumference of the transparent area 12, the first straight side 411 of the rectangular compensation area 41 located at the lateral portion of the transparent area 12 is parallel to a lateral side of the circumference of the transparent area 12.

The rectangular compensation area 41 is distanced from the corresponding edge corner of the transparent area 12 by a distance S2, the first straight side 411 and the second straight side 412 of each rectangular compensation area 41 are distanced from each other by a distance h, the first straight sides 411 of the at least rectangular compensation areas 41 are of a same length, and h of the at least rectangular compensation areas 41 is inversely proportional to S2. That is, the greater the value of S2, the smaller the value of h.

It is understood that, in practice, the values of h and S2 are determined based on the size of pixel electrode that is to be formed. The greater the size of the pixel electrode, the greater the values of h and S2.

In addition, FIG. 5 shows that each second compensation area 31 includes only three rectangular compensation area 41. However, in practice, the greater the size of the pixel electrode, the greater the length of the bottom side of the circumference of the transparent area 12. Therefore, each second compensation area 31 would include more rectangular compensation area 41.

### Embodiment Five

In view of the above-described array substrate, the present disclosure further provides a method for manufacturing an array substrate, comprising:

a step S10 of forming a pixel electrode 52 on a baseplate 51, the pixel electrode 52 including an effective active area 521 and an etched area 522;

a step S20 of etching the etched area 522 of the pixel electrode 52 using a mask 10 by performing an etching process, so as to form a parallelogram-shaped etched area 522 of the pixel electrode 52;

wherein the mask 10 comprises a shielding area 11 and a transparent area 12 corresponding to the etched area 522, a pattern defined by a circumference of the transparent area 12 has a shape of a parallelogram, and both a top side and a bottom side of the circumference of the transparent area 12 includes an exposure compensation area extending towards the shielding area 11.

The present disclosure provides advantageous effects described below. By using a mask 10 to etch the pixel electrode 52, wherein both a top side and a bottom side of the circumference of the transparent area 12 of the mask 10 includes an exposure compensation area, and by providing various masks 10 that have different compensation designs to improve the pattern of the manufactured pixel electrode, the pixel electrode 52 thus formed can has a pattern matching the theoretically designed shape, thus increasing light transparency of display panels.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. An array substrate comprising a baseplate and a pixel electrode disposed on the baseplate, the pixel electrode including an effective active area and a parallelogram-shaped etched area, wherein the etched area is formed using a mask having a transparent area by performing an etching process;
wherein the mask comprises a shielding area and the transparent area corresponding to the etched area, a pattern defined by a circumference of the transparent area has a shape of a parallelogram, and both a top side and a bottom side of the circumference of the transparent area includes an exposure compensation area extending towards the shielding area.

2. The array substrate according to claim 1, wherein each of the exposure compensation areas includes two corner compensation areas at edge corners of the transparent area.

3. The array substrate according to claim 2, wherein each of the exposure compensation areas further includes a side compensation area located between the two corner compensation areas, and the two corner compensation areas are connected to the side compensation area.

4. The array substrate according to claim 3, wherein a circumference of the corner compensation area has a shape of a diamond, a first lateral side of the circumference of the corner compensation area is parallel to a second lateral side of the circumference of the transparent area, and a top side of the circumference of the corner compensation area is parallel to the top side of the circumference of the transparent area.

5. The array substrate according to claim 4, wherein the first lateral side and the second lateral side located at a same side of the transparent area are distanced from each other by a distance a, the top side and a bottom side of the circumference of the corner compensation area are distanced from each other by a distance b, and a top side and a bottom side of the circumference of the side compensation area are distanced from each other by a distance c equal to a value obtained by subtraction of a from b.

6. The array substrate according to claim 2,
wherein each of the corner compensation areas includes two first compensation areas, both circumferences of the two first compensation areas have a same shape and size of a right triangle, a side of the circumference of the first compensation area overlaps with a lateral side of the circumference of the transparent area, and a boundary between the first compensation area and the shielding area is a hypotenuse of the circumference of the first compensation area; and
wherein one of the first compensation areas of each corner compensation area is located at a lateral portion of the transparent area, the other first compensation area of the each corner compensation area is located at a top portion or a bottom portion of the transparent area, and the two first compensation areas of each corner compensation area partially overlap with each other.

7. The array substrate according to claim 2, wherein each of the corner compensation areas includes two second compensation areas, one of the second compensation areas of each corner compensation area is located at a lateral portion of the transparent area, the other second compensation area of the each corner compensation area is located at a top portion or a bottom portion of the transparent area, and a boundary between each second compensation area and the shielding area has a shape of a continuous wave.

8. The array substrate according to claim 7,
wherein each of the second compensation areas includes at least three triangular compensation areas, a circumference of each triangular compensation area has a shape of an isosceles triangle, bases of circumferences of the at least three triangular compensation areas of each second compensation area are of a same length, and legs of circumferences of the at least three triangular compensation areas of each second compensation area are of different length; and
wherein the base of the circumference of the triangular compensation area is distanced from a corresponding edge corner of the transparent area by a distance S 1, the leg of the circumference of the triangular compensation area has a length of K, and K is inversely proportional to S 1.

9. The array substrate according to claim 7, wherein
wherein each of the second compensation areas includes at least three rectangular compensation areas, a circumference of each rectangular compensation area has a shape of a rectangle, the circumference of each rectangular compensation area includes a first straight side and a second straight side remote from the transparent area and parallel to the first straight side, the first straight side of the rectangular compensation area located at the bottom portion or the top portion of the transparent area is parallel to the bottom side of the circumference of the transparent area, and the first straight side of the rectangular compensation area located at the lateral portion of the transparent area is parallel to a lateral side of the circumference of the transparent area; and
wherein the rectangular compensation area is distanced from the corresponding edge corner of the transparent area by a distance S2, the first straight side and the second straight side of each rectangular compensation area are distanced from each other by a distance h, the first straight sides of the at least rectangular compensation areas are of a same length, and h of the at least rectangular compensation areas is inversely proportional to S2.

10. A method for manufacturing an array substrate, comprising:
a step S10 of forming a pixel electrode on a baseplate, the pixel electrode including an effective active area and an etched area;
a step S20 of etching the etched area of the pixel electrode using a mask by performing an etching process, so as to form a parallelogram-shaped etched area of the pixel electrode;
wherein the mask comprises a shielding area and a transparent area corresponding to the etched area, a pattern defined by a circumference of the transparent area has a shape of a parallelogram, and both a top side and a bottom side of the circumference of the transparent area includes an exposure compensation area extending towards the shielding area.
